(19) United States
(12) Patent Application Publication
(10) Pub. No.: US 2009/0160003 A1
(43) Pub. Date: Jun. 25, 2009

(54) IMAGE SENSOR AND METHOD FOR MANUFACTURING THE SAME

(76) Inventors: Sung Hyok Kim, Hwaseong-si (KR); Joon Ku Yoon, Suwon-si (KR)

Correspondence Address: SHERR & VAUGHN, PLLC, 620 HERNDON PARKWAY, SUITE 200, HERNDON, VA, 20170, US

(21) Appl. No.: 12/334,499

(22) Filed: Dec. 14, 2008

(30) Foreign Application Priority Data
Dec. 24, 2007 (KR) 10-2007-0136551

(51) Int. Cl. H01L 31/0232

(52) U.S. Cl. 257/432; 438/70; 257/E31.127

(57) ABSTRACT

Embodiments relate to an image sensor and a method for manufacturing the same. According to embodiments, an image sensor may include a semiconductor substrate and a transistor. An interlayer insulating layer, including a metal line, may be formed on and/or over the semiconductor substrate. A lower electrode may be formed on and/or over the metal line and may be connected with the metal line. A spacer may be formed on a sidewall of the lower electrode. A photo diode may be formed on and/or over an interlayer insulating layer including the lower electrode and the spacer.

The present application claims priority under 35 U.S.C. 119 to Korean Patent Application No. 10-2007-0136551 (filed on Dec. 24, 2007), which is hereby incorporated by reference in its entirety.

### BACKGROUND

An image sensor may be a semiconductor device that may convert an optical image into an electric signal. Image sensors may generally be classified into charge coupled device (CCD) image sensor and complementary metal oxide semiconductor (CMOS) image sensor (CIS). A CIS may include a photo diode and a MOS transistor, which may be formed in a unit pixel. A CIS may obtain an image by sequentially detecting electrical signals of unit pixels in a switching manner. In a CIS structure, a photo diode region and a transistor may be horizontally arranged in a semiconductor substrate. The photo diode region may convert a light signal into an electrical signal, and the transistor may process the electrical signal. In a horizontal type CIS according to the related art, a photo diode and a transistor may be horizontally formed adjacent to each other. Therefore, an additional region to form the photo diode may be required.

### SUMMARY

Embodiments relate to an image sensor and a method for manufacturing the same. Embodiments relate to an image sensor and a method for manufacturing the same that may vertically integrate transistor circuitry and a photodiode, and may prevent crosstalk and noise phenomenon of the photo diode.

According to embodiments, an image sensor may include at least one of the following. A semiconductor substrate including a transistor. An interlayer insulating layer including a metal line on and/or over the semiconductor substrate. A lower electrode on and/or over the metal line so as to be connected with the metal line. A spacer on and/or over a sidewall of the lower electrode. A photo diode on and/or over the interlayer insulating layer including the lower electrode and the spacer.

According to embodiments, a method for manufacturing an image sensor may include at least one of the following. Forming an interlayer insulating layer including a metal line on and/or over a semiconductor substrate including a transistor. Forming a lower electrode on and/or over the metal line such that the lower electrode may be connected with the metal line. Forming a spacer on and/or over a sidewall of the lower electrode. Forming a photo diode on and/or over the interlayer insulating layer including the lower electrode and the spacer.

### DRAWINGS

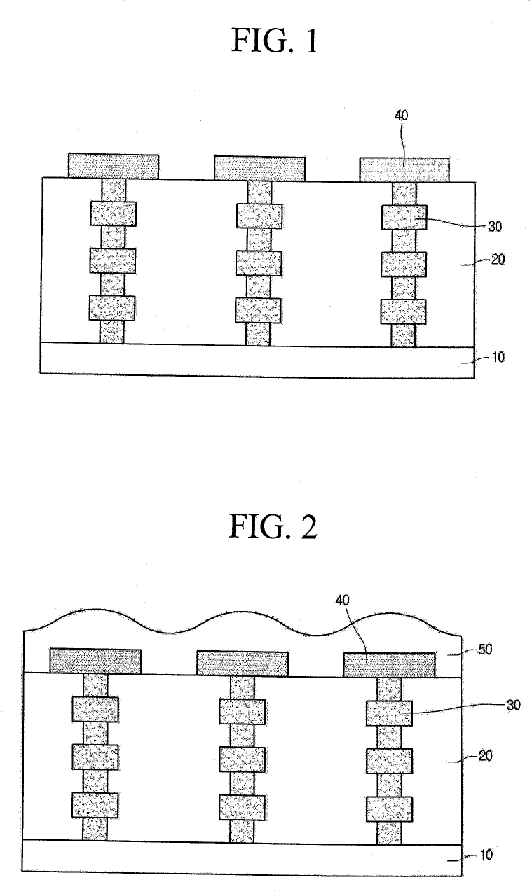

Example FIGS. 1-6 are sectional views illustrating an image sensor and a method for manufacturing an image sensor, according to embodiments.

### DESCRIPTION

Example FIG. 6 is a sectional view of an image sensor, according to embodiments. Referring to example FIG. 6, interlayer insulating layer 20, which may include metal line 30, may be disposed on and/or over semiconductor substrate 10. According to embodiments, a transistor may be disposed in each pixel on and/or over semiconductor substrate 10. Interlayer insulating layer 20 may have a multi-layer structure. According to embodiments, interlayer insulating layer 20 may be formed of one of oxide and nitride. According to embodiments, interlayer insulating layer 20 may be formed in a dual layer structure of oxide layer and nitride layer. Metal line 30 may penetrate interlayer insulating layer 20 and may be formed in plurality. According to embodiments, metal line 30 may be formed for each unit pixel and may be electrically connected with circuitry of semiconductor substrate 10.

Lower electrode 40 may be disposed on and/or over metal line 30. According to embodiments, lower electrode 40 may be formed of at least one of Cr, Ti, TiN, Ta, TaN, Al, Cu, and W. Lower electrode 40 may be formed to have a thickness in a range of approximately 50˜200 Å. Lower electrode 40 may be disposed on and/or over metal line 30 and interlayer insulating layer 20 such that metal line 30 may not be exposed. According to embodiments, lower electrode 40 may be disposed on and/or over each metal line 30 provided per unit pixel, and lower electrode 40 in one pixel may be spaced apart from lower electrode 40 in another pixel.

Spacer 55 may be disposed on and/or over both sidewalls of lower electrode 40. According to embodiments, spacer 55 may be formed of an insulator, such as oxide or nitride. According to embodiments, spacer 55 on a sidewall of lower electrode 40 may be formed so as to be spaced apart from or contact spacer 55 on and/or over the sidewall of a neighboring lower electrode 40. According to embodiments, spacer 55 may be formed on and/or over both sidewalls of lower electrode 40 and may separate lower electrode 40 in one pixel from lower electrode 40 in another pixel.

A photo diode may be disposed on and/or over interlayer insulating layer 20 including lower electrode 40 and spacer 55. The photo diode may include first conductive type conduction layer 60, intrinsic layer 70, and second conductive type conduction layer 80. According to embodiments, first conductive type conduction layer 60 may be an n-type amorphous silicon layer, intrinsic layer 70 may be an intrinsic amorphous silicon layer, and second conductive type conduction layer 80 may be a p-type amorphous silicon layer. Since the photo diode may be formed conformally on and/or over a surface of lower electrode 40 and may protrude more from an upper surface of interlayer insulating layer 20, the photo diode may have substantially a wave form. According to embodiments, the photo diode over lower electrode 40 may be formed in a substantially convex shape and the photo diode between the lower electrodes 40 may be formed in a substantially concave shape. Light may be focused on lower electrode 40 due to the convex form of the photo diode.

According to embodiments, photons may be generated in the photo diode and may be gathered into only lower electrode 40. This may prevent crosstalk and noise from being generated. This may be because spacer 55 may be formed on and/or over both sidewalls of lower electrode 40. According to embodiments, photons generated in the photo diode corresponding to a region between the lower electrodes 40 may be blocked from moving to lower electrode 40 by spacer 55. This may prevent crosstalk and noise from being generated.

Upper electrode 90 may be disposed on and/or over the photo diode. Upper electrode 90 may be formed of a transparent electrode that may have a high light transmission and high conductivity. According to embodiments, upper electrode 90 may be formed of one of indium tin oxide (ITO), carbon tin oxide (CTO), and ZnO2.

Color filter 100 may be provided for each unit pixel on and/or over upper electrode 90. Color filter 100 may be formed one by one per unit pixel, and filters incident light to separate colors. According to embodiments, color filter 100 may be made of three different colors, i.e., red (R), green (G) and blue (B).

According to embodiments, an image sensor may enhance a fill factor of a photo diode since the photo diode may be formed on and/or over a semiconductor substrate including a transistor. According to embodiments, since the photo diode may be separated per unit pixel by a spacer formed on sidewalls of the lower electrode, crosstalk and noise generation may be minimized or prevented.

A method for manufacturing an image sensor according to embodiments may be described with reference to example FIGS. 1 to 6. Referring to example FIG. 1, interlayer insulating layer 20, which may include a metal line 30, may be formed on and/or over a semiconductor substrate 10.

According to embodiments, a transistor connected with a photo diode (described below) may convert received photocharges to an electrical signal and may be formed in each pixel on and/or over semiconductor substrate 10. According to embodiments, the transistor may be any one of 3Tr, 4Tr, and 5Tr. Other configurations could be used, according to embodiments. Interlayer insulating layer 20 and metal line 30 may be formed on and/or over semiconductor substrate 10, and may provide for connection with a power line or a signal line. Interlayer insulating layer 20 may be formed in a multi-layer structure. According to embodiments, interlayer insulating layer 20 may be formed of oxide or nitride. According to embodiments, interlayer insulating layer 20 may be formed in a dual layer structure of oxide layer and nitride layer.

Metal line 30 may penetrate interlayer insulating layer 20 and may be formed in plurality. According to embodiments, metal line 30 may be formed of various conductive materials including metals, alloys or salicides. According to embodiments, materials may include copper, cobalt, tungsten, or other metals. Metal line 30 may deliver electrons that may be generated in the photo diode to the transistor disposed below. According to embodiments, metal line 30 may be formed for each unit pixel such that metal line 30 may be connected with an impurity doped region formed in semiconductor substrate 10.

Lower electrode 40 may be formed per unit pixel on and/or over interlayer insulating layer 20 and may be connected with metal line 30. Lower electrode 40 may be formed by depositing a metal layer, for example using a PVD, and patterning the deposited metal layer. According to embodiments, lower electrode 40 may be formed of any one of Cr, Ti, TiN, Ta, TaN, Al, Cu, and W. According to embodiments, lower electrode 40 may have a thickness in a range of approximately 50˜200 Å. According to embodiments, the patterning of lower electrode 40 may be performed by a dry etch using Cl2 and O2 gas. Lower electrode 40 may be formed on and/or over interlayer insulating layer 20 and may be electrically connected with metal line 30. According to embodiments, lower electrodes 40 may be spaced apart from one another to selectively expose interlayer insulating layer 20. According to embodiments, as an area of lower electrode 40 increases, an amount that the photo diode collects photocharges may increase.

Referring to FIG. example 2, insulating layer 50 may be formed on and/or over interlayer insulating layer 20, including lower electrode 40. According to embodiments, insulating layer 50 may be formed of oxide or nitride and may be formed with a thickness in a range of approximately 100˜5000 Å.

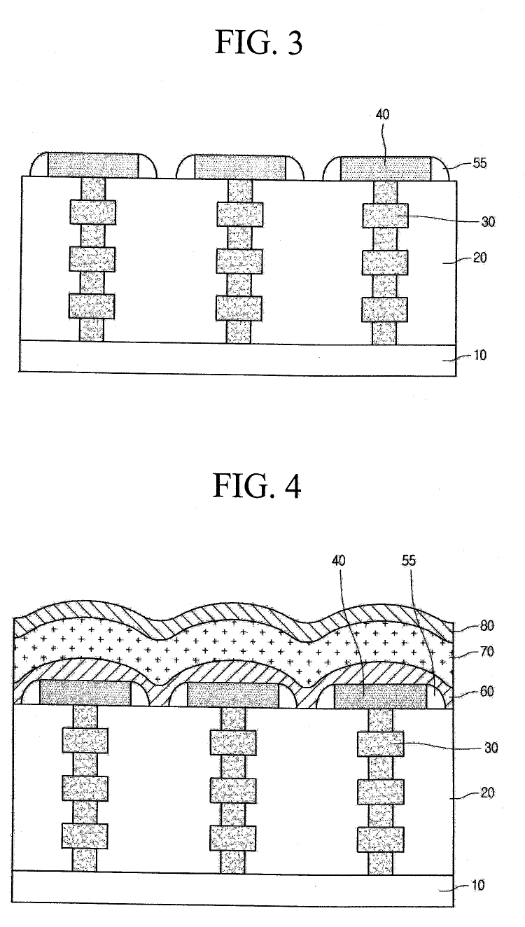

Referring to example FIG. 3, spacer 55 may be formed on both sidewalls of lower electrode 40. According to embodiments, spacer 55 may be formed on only both sidewalls of lower electrode 40 by performing a blanket etch to insulating layer 50. Lower electrode 40 in one pixel may be separated from lower electrode 40 in another neighboring pixel by spacer 55. Spacer 55 formed on the sidewall of lower electrode 40 may be formed to be either spaced apart from or contact spacer 55 on the sidewall of an adjacent lower electrode 40. According to embodiments, lower electrodes 40 may be in separated by spacer 55.

Referring to example FIG. 4, a photo diode may be formed on and/or over interlayer insulating layer 20 including lower electrode 40 and spacer 55. According to embodiments, the photo diode may use a NIP diode. A NIP diode may be formed in a junction structure of a metal layer, an n-type amorphous silicon layer, an intrinsic amorphous silicon layer, and a p-type amorphous silicon layer. A NIP diode may be a photo diode having a junction structure in which the intrinsic amorphous silicon layer, which may be a pure semiconductor, may be disposed between the p-type amorphous silicon layer and the metal layer. Since all of the intrinsic amorphous silicon layer between the p-type amorphous silicon layer and the metal layer may become a depletion region, it may be advantageous to generate and hold charges.

According to embodiments, a NIP diode may be used as the photo diode. According to embodiments, photo diodes having a P-I-N, N-I-P, or I-P structure may also be used. For purposes of clarity and example, reference will be made to a photo diode having the N-I-P structure. According to embodiments, in a NIP diode, an n-type amorphous silicon layer may be referred to as first conductive type conduction layer 60, an intrinsic amorphous silicon layer may be referred to as intrinsic layer 70, and a p-type amorphous silicon layer may be referred to as second conductive type conduction layer 80.

According to embodiments, a photo diode may be formed as follows. First conductive type conduction layer 60 may be formed on and/or over interlayer insulating layer 20. According to embodiments, subsequent processes may be performed without forming first conductive type conduction layer 60. First conductive type conduction layer 60 may act as N-layer of the N-I-P diode. According to embodiments, first conductive type conduction layer 60 may be an N-type conduction layer. According to embodiments, other configurations could be used. First conductive type conduction layer 60 may be formed by a CVD. According to embodiments, first conductive type conduction layer 60 may be formed by a PECVD. For example, first conductive type conduction layer 60 may be an N-type amorphous silicon layer that may be formed by a PECVD in which silane gas (SiH4) may be mixed with one of PH3 and P2H5, or the like. A deposition may be performed in a temperature range of approximately 100˜400° C. First conductive type conduction layer 60 may be formed in a thickness range of approximately 50˜1000 Å.

Intrinsic layer 70 may be formed on and/or over first conductive type conduction layer 60. Intrinsic layer 70 may acts as I-layer of the N-I-P diode. Intrinsic layer 70 may be formed of intrinsic amorphous silicon. Intrinsic layer 70 may be formed by a CVD. According to embodiments, intrinsic layer 70 may be formed by a PECVD or the like. For example, intrinsic layer 70 may be formed of amorphous silicon by a PECVD that may use silane (SiH₄) gas. According to embodiments, intrinsic layer 70 may be formed to have a thickness in a range of approximately 500˜12000 Å. According to embodiments, intrinsic layer 70 may be formed approximately 10˜1,000 times thicker than first conductive type conduction layer 60. This may be because an increase in a thickness of the intrinsic layer may increase a depletion region of a diode such that more photocharges may be stored and generated.

Second conductive type conduction layer 80 may be formed on and/or over intrinsic layer 70. According to embodiments, second conductive type conduction layer 80 and intrinsic layer 70 may be formed in situ. Second conductive type conduction layer 80 may act as P-layer of the N-I-P diode. According to embodiments, second conductive type conduction layer 80 may be a P-type conduction layer, but is not limited thereto. Second conductive type conduction layer 80 may be formed by a CVD, and may be formed by a PECVD. According to embodiments, second conductive type conduction layer 80 may be a P-type amorphous silicon layer which may be formed by a PECVD in which silane gas (SiH4) may be mixed with BH3, B2H6 or the like. Deposition may be performed in a temperature range of approximately 100˜400° C. Second conductive type conduction layer 80 may be formed in a thickness range of approximately 50˜2000 Å.

Semiconductor substrate 10 may include a transistor and a photo diode that may be vertically integrated, and may therefore be capable of approximating a fill factor of the photo diode to 100%. This may maximize a fill factor.

According to embodiments, since a photo diode may be formed along a height difference between lower electrode 40 and interlayer insulating layer 20, a photo diode may have substantially a wave form. According to embodiments, a photo diode formed on and/or over lower electrode 40 may have a substantially convex shape and a photo diode formed between the lower electrodes 40 may have a substantially concave shape. Accordingly, photons generated in the photo diode may be gathered into lower electrode 40 of a corresponding unit pixel, which may enhance a light condensing efficiency.

According to embodiments, spacer 55, which may be formed on and/or over sidewalls of lower electrode 40 collecting photons and delivering the gathered photons to metal line 30, may separate a photo diode into unit pixels. According to embodiments, since spacer 55 may be formed on and/or over both sidewalls of lower electrode 40, photons generated in the photo diode corresponding to lower electrode 40 may be gathered into lower electrode 40 of the corresponding unit pixel. According to embodiments, photons generated in the photo diode corresponding to a region between lower electrodes 40 may be blocked from moving to an adjacent lower electrode 40. Accordingly, since photons generated in the photo diode corresponding to each pixel may be gathered into only a corresponding lower electrode 40, crosstalk and noise generation may be minimized or prevented.

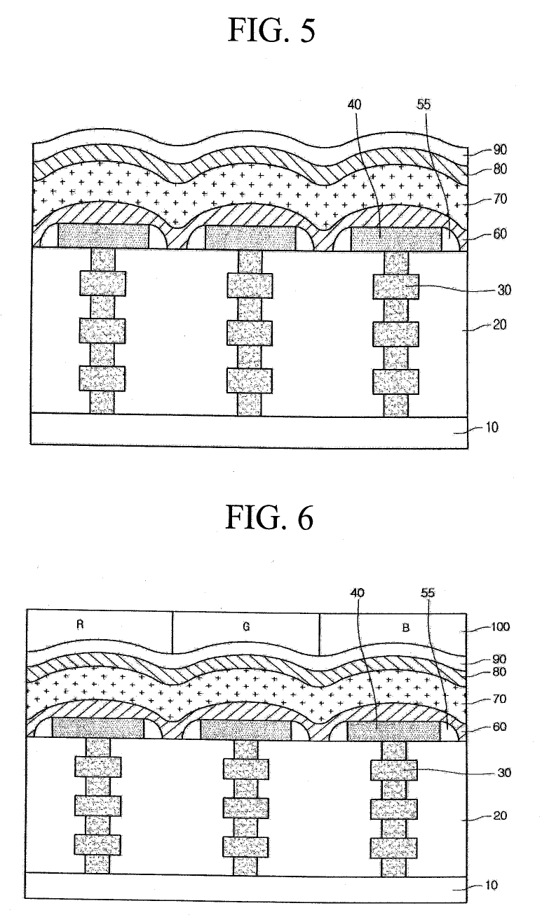

Referring to example FIG. 5, upper electrode 90 may be formed on and/or over the photo diode. Upper electrode 90 may be formed of a transparent electrode that may have a high light transmission and high conductivity. According to embodiments, upper electrode 90 may be formed of one of indium tin oxide (ITO), carbon tin oxide (CTO), and ZnO2. According to embodiments, since upper electrode 90 may be formed conformally on and/or over a surface of the photo diode, upper electrode 90 may be formed in a wave form.

Referring to example FIG. 6, color filter 100 may be formed for each unit pixel on and/or over upper electrode 90. Color filter 100 may be formed one by one per unit pixel, and may filter incident light into separate colors. Color filter 100 may include three different colors, i.e., red (R), green (G) and blue (B). According to embodiments, a microlens may be formed on and/or over color filter 100.

According to embodiments, an image sensor and a method for manufacturing the same may provide a vertical integration of the transistor circuitry and the photo diode. According to embodiments, a vertical integration of transistor circuitry and a photo diode may approximate a fill factor to 100%. According to embodiments, vertical integration may provide a higher sensitivity than a related art structure about the same pixel size.

According to embodiments, each unit pixel may realize more complicated circuitry without a decrease in the sensitivity. According to embodiments, in realizing unit pixels of the photo diode, light sensitivity may be enhanced by increasing a surface area of a photo diode in a unit pixel. According to embodiments, since a device isolation region may be formed between photo diodes, crosstalk and noise generation may be minimized or prevented.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An device comprising:
a semiconductor substrate including a transistor;
an interlayer insulating layer including a metal line over the semiconductor substrate;
a lower electrode over the metal line and connected to the metal line;
a spacer over a sidewall of the lower electrode; and
a photodiode over the interlayer insulating layer including the lower electrode and the spacer.

2. The device of claim 1, wherein the spacer comprises an insulating layer.

3. The device of claim 1, wherein the lower electrode has a thickness in a range of approximately 50-200 Å.

4. The device of claim 3, wherein the spacer is spaced apart from a spacer of an adjacent lower electrode.

5. The device of claim 3, wherein the spacer is in contact with a spacer of an adjacent lower electrode.

6. The device of claim 3, wherein the lower electrode comprises one of Cr, Ti, TiN, Ta, TaN, Al, Cu, and W.

7. The device of claim 1, comprising an upper electrode over the photodiode.

8. The device of claim 1, comprising a color filter over the photodiode.

9. The device of claim 1, wherein the photodiode comprises a substantially convex shape at a region over the lower electrode and a substantially concave shape at a region over the interlayer insulating layer.

10. A method comprising:
forming an interlayer insulating layer including a metal line over a semiconductor substrate including a transistor;
forming a lower electrode over the metal line such that the lower electrode is connected with the metal line;
forming a spacer over a sidewall of the lower electrode; and
forming a photodiode over the interlayer insulating layer including the lower electrode and the spacer.

11. The method of claim 10, wherein forming the spacer comprises:
forming an insulating layer over the interlayer insulating layer including the lower electrode; and
performing a blanket etch to the insulating layer.

12. The method of claim 10, comprising:
forming a first conductive type conduction layer with a thickness in a range of approximately 50-1000 Å over the lower electrode, the spacer, and the interlayer insulating layer;
forming an intrinsic layer over the first conductive type conduction layer with a thickness in a range of approximately 500-12000 Å; and
forming a second conductive type conduction layer over the intrinsic layer with a thickness in a range of approximately 50-2000 Å.

13. The method of claim 10, wherein the lower electrode has a thickness in a range of approximately 50-200 Å.

14. The method of claim 13, wherein the spacer is formed to be spaced apart from a spacer of an adjacent lower electrode.

15. The method of claim 13, wherein the spacer is formed to be in contact with a spacer of an adjacent lower electrode.

16. The method of claim 13, wherein the lower electrode comprises one of Cr, Ti, TiN, Ta, TaN, Al, Cu, and W.

17. The method of claim 10, comprising forming an upper electrode over the photodiode.

18. The method of claim 10, comprising forming a color filter over the photodiode.

19. The method of claim 10, wherein the photodiode is deposited conformally over a surface of the interlayer insulating layer including the lower electrode, and the photodiode corresponding to a position of the lower electrode is formed in substantially a convex shape.

20. The method of claim 10, wherein the photodiode comprises a substantially convex shape in a region corresponding to a position of the lower electrode and a substantially concave shape in a region corresponding to a position of the interlayer insulating layer.
